(19) United States
(12) Patent Application Publication
(10) Pub. No.: US 2015/0348963 A1
(43) Pub. Date: Dec. 3, 2015

(54) CYLINDER-SHAPED STORAGE NODE WITH SINGLE-LAYER SUPPORTING STRUCTURE

(71) Applicant: INOTERA MEMORIES, INC., Taoyuan (TW)

(72) Inventors: Hai-Han Hung, Taoyuan County (TW); Ping-Hung Kuo, Chiayi City (TW); Yi-Wei Chuang, Taipei City (TW)

(73) Assignee: INOTERA MEMORIES, INC., Taoyuan (TW)

(21) Appl. No.: 14/290,987

(22) Filed: May 30, 2014

(51) Int. Cl. H01L 27/08; H01L 49/02; H01L 23/32

(52) U.S. Cl. CPC H01L 27/0805; H01L 23/32; H01L 28/60

(57) ABSTRACT

A semiconductor structure includes a substrate having thereon a conductive region, at least one cylinder-shaped container on the conductive region, and a supporting structure having at least two stripe shaped portions arranged in parallel to each other and at least one retaining ring between the two stripe shaped portions. The retaining ring retains and structurally supports the cylinder-shaped container electrode.

### BACKGROUND OF THE INVENTION

1. Field of the Invention

The present invention relates generally to a semiconductor structure. More specifically, the present invention relates to a capacitor or a cylinder-shaped storage node of a capacitor with a single-layer supporting structure. A self-aligned method for forming such single-layer supporting structure is also disclosed.

2. Description of the Prior Art

As the level of integration continues to increase in integrated circuitry, electronic components are formed to increasing the smaller dimensions. One type of component utilized in integrated circuitry is a capacitor. It is well known that capacitors may serve as charge storage elements of dynamic random access memory (DRAM) devices.

Capacitors are becoming increasingly tall and thin in an effort to reduce the footprint of individual capacitors, and thereby conserve semiconductor real estate. Current capacitor dimensions are approaching the limits attainable by conventional processing, and it is desired to develop new processing so that capacitors may be scaled to increasingly thinner dimensions.

A common capacitor construction is a so-called container-shaped storage node device. The container-shaped storage nodes are first formed within densely-packed, high-aspect-ratio holes etched into a template or support structure. After removing the template layer, a dielectric material and a capacitor cell plate are formed on the container. Unfortunately, high aspect-ratio container-shaped storage nodes are structurally weak, and subject to toppling, twisting and/or breaking from an underlying base.

To avoid toppling of high aspect-ratio container-shaped storage node, a lattice-type supporting structure has been developed. However, the prior art has several drawbacks. For example, an extra photomask or lithographic step is typically required to open the support lattice nitride layer for formation of double side DRAM capacitors. Besides, the misalignment or lithographic overlay shift becomes a major problem as the critical dimension continues to shrink.

### SUMMARY OF THE INVENTION

It is one objective to provide an improved cylinder-shaped storage node of a capacitor with a single-layer supporting structure in order to solve the above-mentioned prior art problems and shortcomings.

According to one aspect of the invention, a semiconductor structure includes a substrate having thereon at least one conductive region; a plurality of cylinder-shaped container electrodes disposed on the substrate, wherein each of the cylinder-shaped container electrodes has a horizontal portion that is in direct contact with the at least one conductive region and a vertical sidewall portion connecting the horizontal portion; and a supporting structure comprising a plurality of stripe shaped portions arranged in parallel to one another and a plurality of retaining rings between two adjacent stripes of the plurality of stripe shaped portions, wherein each of the plurality of retaining rings retains each of the plurality of cylinder-shaped container electrodes, wherein the plurality of stripe shaped portions and the plurality of retaining rings are situated in the same horizontal plane.

According to one embodiment of the invention, the plurality of cylinder-shaped container electrodes are arranged in rows, and wherein each row of the cylinder-shaped container electrodes is clamped and sandwiched by two adjacent stripes of the plurality of stripe shaped portions.

According to one embodiment of the invention, the plurality of stripe shaped portions and the plurality of retaining rings are made from one single homogenous material layer.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

The accompanying drawings are included to provide a further understanding of the embodiments, and are incorporated in and constitute apart of this specification. The drawings illustrate some of the embodiments and, together with the description, serve to explain their principles. In the drawings:

FIG. 1 to FIG. 10 shows a self-aligned method for forming a cylinder-shaped storage node container of a capacitor that is structurally supported by a single-layer supporting structure, wherein:

FIG. 2A is a plan view showing a portion of the container openings in the memory array and FIG. 2B is a sectional view taken along line I-I′ of FIG. 2A;

FIG. 3A is a plan view showing the containers after removing the top silicon oxide layer and FIG. 3B is a sectional view taken along line I-I′ of FIG. 3A;

FIG. 4A is a plan view showing the containers after tilt-angle ion implantation and FIG. 4B is a sectional view taken along line I-I′ of FIG. 4A;

FIG. 5A is a plan view showing the containers after selective removal of the undoped polysilicon layer, FIG. 5B is a sectional view taken along line I-I′ of FIG. 5A, and FIG. 5C is a sectional view taken along line II-II′ of FIG. 5A;

FIG. 6A is a plan view showing the containers after depositing an ALD oxide layer in a blanket manner, FIG. 6B is a sectional view taken along line I-I′ of FIG. 6A, and FIG. 6C is a sectional view taken along line II-II′ of FIG. 6A;

FIG. 7A is a plan view showing the containers after formation of an annular oxide spacer, FIG. 7B is a sectional view taken along line I-I′ of FIG. 7A, and FIG. 7C is a sectional view taken along line II-II′ of FIG. 7A;

FIG. 8A is a plan view showing the containers after removal of the resist layer and the implanted layer, and FIG. 8B is a sectional view taken along line I-I′ of FIG. 8A;

FIG. 9A is a plan view showing the containers after removal of the PSG layer, FIG. 9B is a sectional view taken along line I-I′ of FIG. 9A, and FIG. 9C is a sectional view taken along line II-II′ of FIG. 9A; and

FIG. 10 is a sectional diagram showing a capacitor structure.

It should be noted that all the figures are diagrammatic. Relative dimensions and proportions of parts of the drawings are exaggerated or reduced in size, for the sake of clarity and convenience. The same reference signs are generally used to refer to corresponding or similar features in modified and different embodiments.

### DETAILED DESCRIPTION

In the following description, numerous specific details are given to provide a thorough understanding of the invention. It will, however, be apparent to one skilled in the art that the invention may be practiced without these specific details. Furthermore, some well-known system configurations and process steps are not disclosed in detail, as these should be well-known to those skilled in the art.

Likewise, the drawings showing embodiments of the apparatus are semi-diagrammatic and not to scale and some dimensions are exaggerated in the figures for clarity of presentation. Also, where multiple embodiments are disclosed and described as having some features in common, like or similar features will usually be described with like reference numerals for ease of illustration and description thereof.

The terms “semiconductive substrate,” “semiconductor construction” and “semiconductor substrate” used herein include any construction comprising semiconductive materials, including, but not limited to, bulk semiconductive materials such as a semiconductive wafer (either alone or in assemblies comprising other materials), and semiconductive material regions (either alone or in assemblies comprising other materials). The term “substrate” refers to any supporting structure, including, but not limited to, the semiconductive substrates described above.

The term “horizontal” as used herein is defined as a plane parallel to the conventional major plane or surface of the semiconductor substrate, regardless of its orientation. The term ^{“}vertical” refers to a direction perpendicular to the horizontal as just defined. Terms, such as “on”, “above”, “below”, “bottom”, “top”, “side”(as in “sidewall”), “higher”, “lower”, “over”, and “under”, are defined with respect to the horizontal plane.

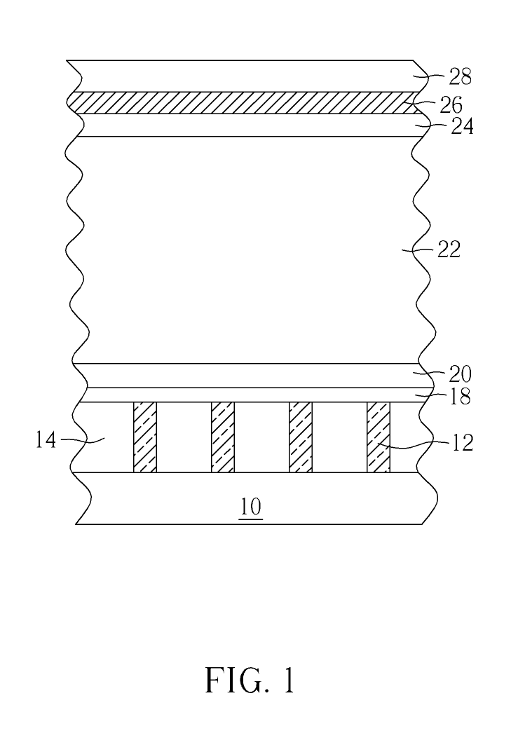

Please refer to FIG. 1 to FIG. 10. As shown in FIG. 1, a substrate 10 is provided to serve as a base for forming integrated devices, components, or circuits. The substrate 10 may comprise, consist essentially of, or consist of monocrystalline silicon, and may be referred to as a semiconductor substrate, or as a portion of a semiconductor substrate. Although the substrate 10 in this embodiment is shown to be homogenous, the substrate 10 may comprise numerous materials in some embodiments. For instance, the substrate 10 may correspond to a semiconductor substrate containing one or more materials associated with integrated circuit fabrication. In such embodiments, such materials may correspond to one or more of refractory metal materials, barrier materials, diffusion materials, insulator materials, etc.

According to the embodiment, at least one conductive region 12 is disposed in the substrate 10. For example, the conductive region 12 may be a contact, a source/drain doping region, or a landing pad. In a case that the conductive region 12 is a contact such as tungsten contact, the conductive region 12 is embedded in a dielectric layer 14 such as a silicon oxide layer. Initially, the conductive region 12 and the dielectric layer 14 may be covered with a stop layer 18, for example, a nitride etching stop layer. An undoped silicate glass (USG) layer 20 is deposited on the stop layer 18. A phosphorus silicate glass (PSG) layer 22 that acts as a template layer for forming containers is deposited on the USG layer 20. A silicon nitride layer 24 is then deposited on the PSG layer 22. An undoped polysilicon layer 26 is deposited on the silicon nitride layer 24. A silicon oxide layer 28 is then deposited on the undoped polysilicon layer 26.

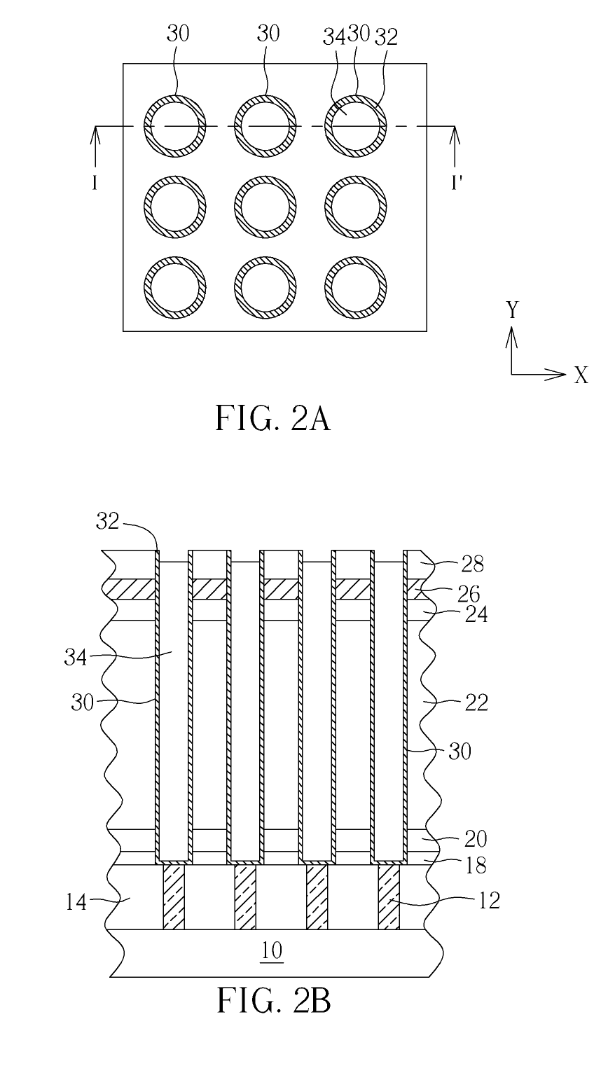

As shown in FIG. 2A and FIG. 2B, a lithographic process and a dry etching process are carried out to form high-aspect-ratio container openings 30 into the silicon oxide layer 28, the undoped polysilicon layer 26, the silicon nitride layer 24, the PSG layer 22, the USG layer 20, and the stop layer 18. For the sake of simplicity, only a 3×3 container array is illustrated in FIG. 2A. As can be seen in FIG. 2B, each of the container openings 30 extends through the silicon oxide layer 28, the undoped polysilicon layer 26, the silicon nitride layer 24, the PSG layer 22, the USG layer 20, and the stop layer 18, thereby revealing a top surface of the conductive region 12.

Subsequently, a conformal conductive layer such as Ti and/or TiN is deposited on the silicon oxide layer 28 and into the container openings 30. The conductive layer conformally covers the interior surfaces of the container openings 30. A resist layer 34 is then formed on the conductive layer and the resist layer 34 completely fills the container openings 30. The conductive layer on the silicon oxide layer 28 is then removed by using a chemical mechanical polishing (CMP) process to reveal the top surface of the silicon oxide layer 28. The remaining conductive layer within each of the container openings 30 constitutes a cylinder-shaped storage node container (hereinafter “container”) 32, which acts as a bottom electrode of a capacitor.

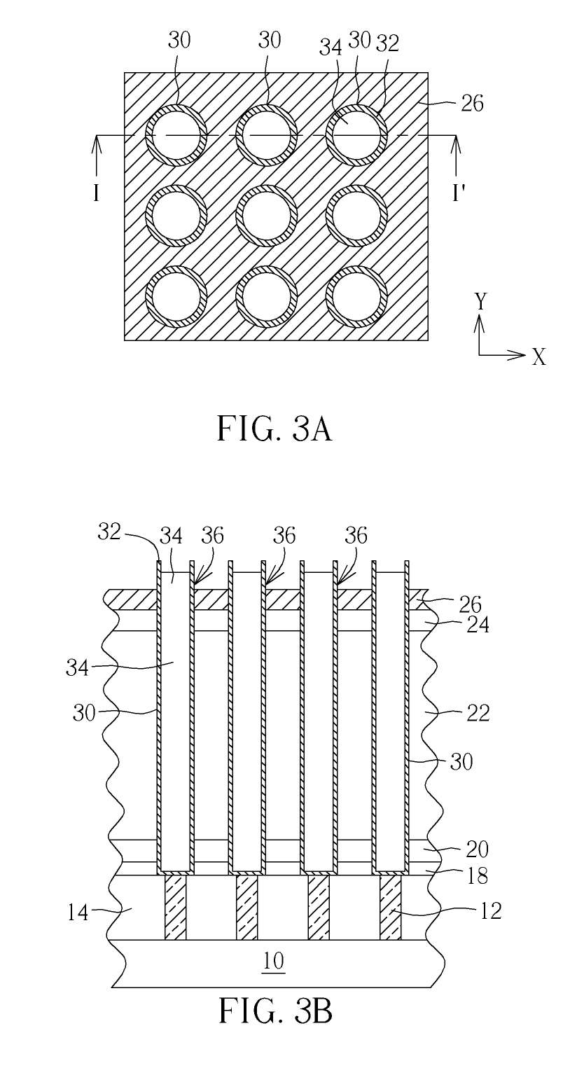

As shown in FIG. 3A and FIG. 3B, subsequently, the silicon oxide layer 28 is completely removed to reveal the top surface of the undoped polysilicon layer 26. At this point, a tip portion of the container 32 protrudes from the top surface of the undoped polysilicon layer 26, thereby forming a step height 36 that is determined by the thickness of the silicon oxide layer 28. For example, to selectively remove the silicon oxide layer 28 without etching the underlying undoped polysilicon layer 26, the container 32, and the resist layer 34, a wet chemistry using HF based etchant may be employed.

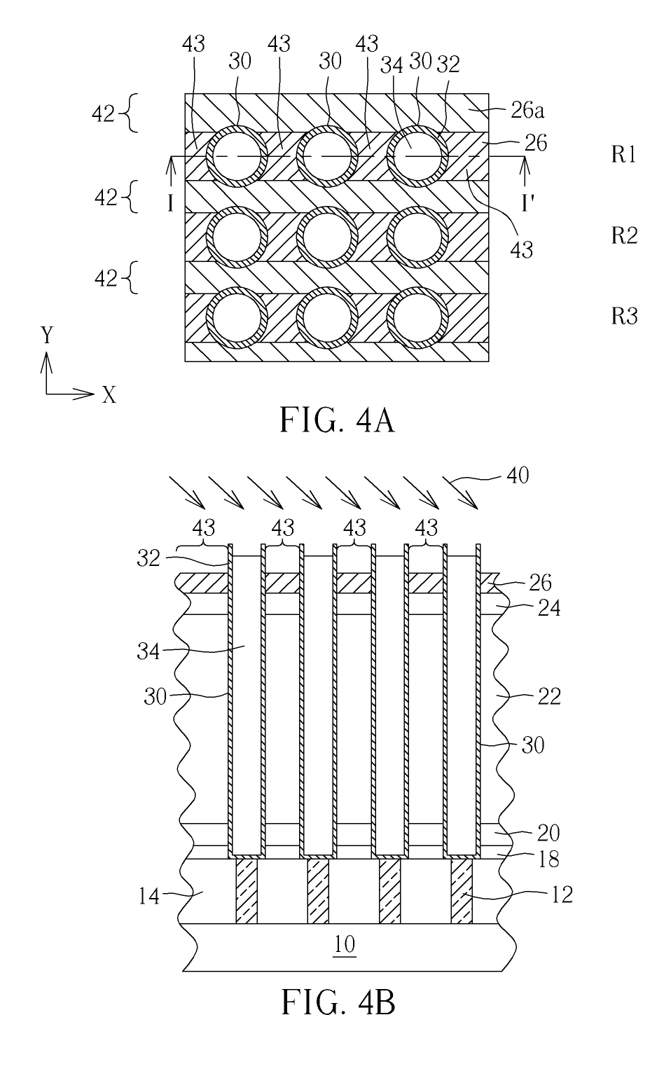

As shown in FIG. 4A and FIG. 4B, a tilt-angle ion implantation process 40 is performed to implant pre-selected dopants such as boron into the stripe shaped regions 42 that are un-shadowed by the protrudent tip portion of the container 32, thereby forming implanted layer 26a. As can be seen in FIG. 4A, the alternate stripe shaped regions 42 are parallel with one another and extend along a reference x-axis. Each of the stripe shaped regions 42 is situated between two adjacent rows of container openings 30. In FIG. 4A, only three rows R₁, R₂, R₃ of the container openings 30 along the reference x-axis direction are illustrated.

The shadowed regions 43 between the container openings 30 along reference x-axis direction are not doped with the pre-selected dopants. It is to be understood that the tilt-angle ion implantation process 40 may comprise at least one ion implant step or multiple ion implant steps utilizing the same or different implant conditions including implant angle, energy, dose, etc. In some cases, the wafer can be rotated 180° for another tilt angle implant. Preferably, the protrudent tip portion of the container 32 has adequate step height for shadowing the tilt angle implant.

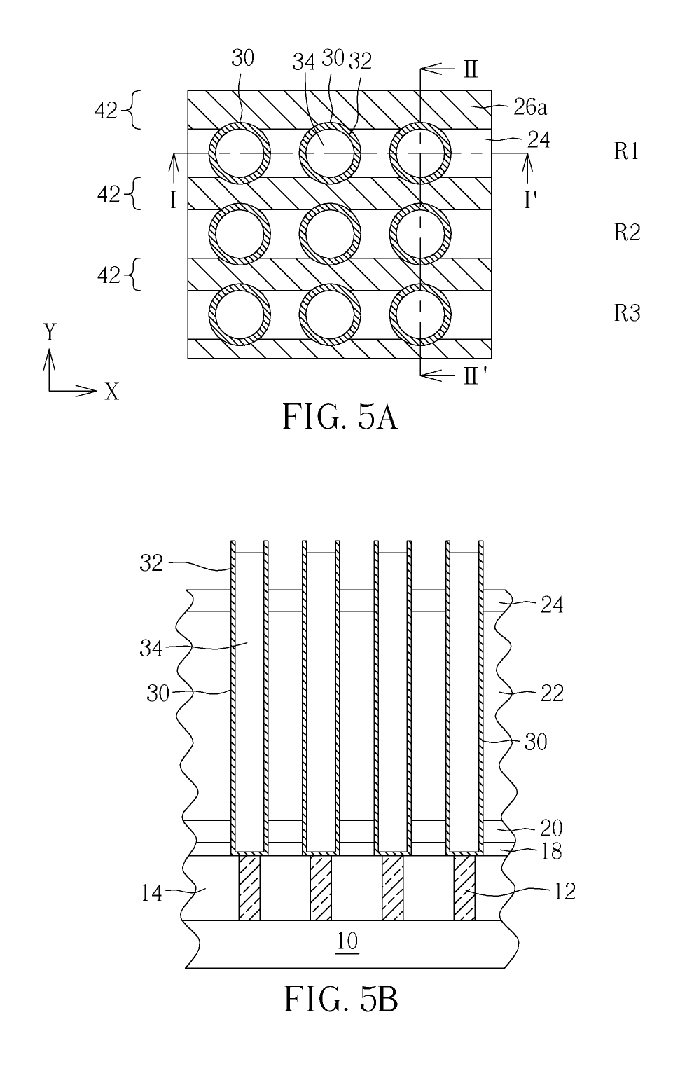

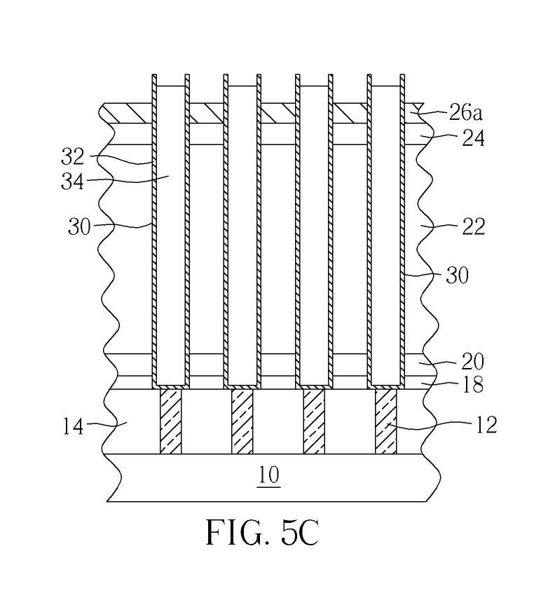

FIG. 5A is a plan view showing the containers after selective removal of the undoped polysilicon layer. FIG. 5B is a sectional view taken along line I-I′ of FIG. 5A. FIG. 5C is a sectional view taken along line II-II′ of FIG. 5A. As shown in FIGS. 5A, 5B and 5C, the undoped polysilicon layer 26 within the shadowed regions 43 is removed, leaving the implanted layer 26a within the stripe shaped regions 42 substantially intact. To selectively remove the undoped polysilicon layer 26 within the shadowed regions 43, a dilute NH₄OH, TMAH, or KOH may be used. After the removal of the undoped polysilicon layer 26 within the shadowed regions 43, a portion of the top surface of the silicon nitride layer 24 is revealed. As can be seen in FIG. 5A and FIG. 5C, the implanted layer 26a within the stripe shaped regions 42 is in direct contact with the outer sidewall surface of the container 32.

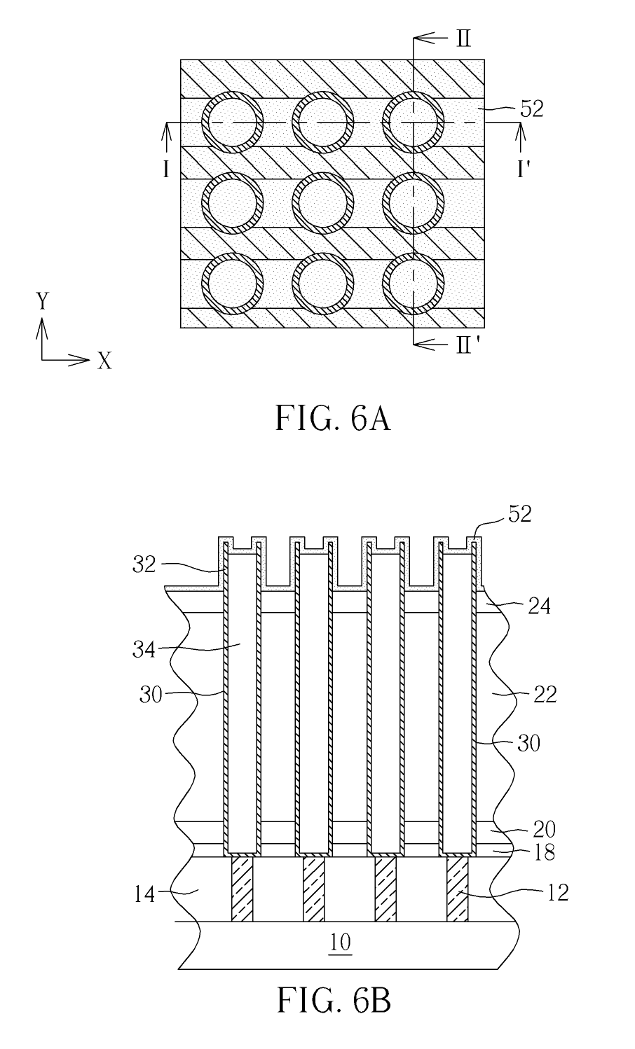

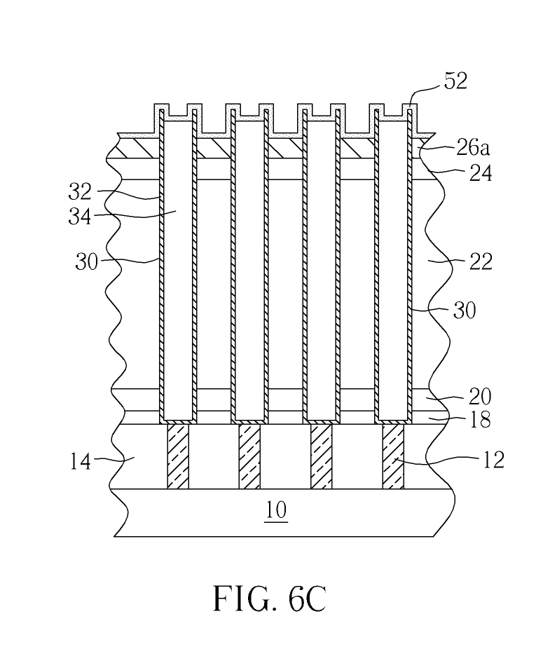

FIG. 6A is a plan view showing the containers after depositing an ALD oxide layer in a blanket manner, FIG. 6B is a sectional view taken along line I-I′ of FIG. 6A, and FIG. 6C is a sectional view taken along line II-II′ of FIG. 6A. As shown in FIGS. 6A, 6B and 6C, a thin silicon oxide layer 52 is deposited in a blanket manner. The silicon oxide layer 52 may be deposited by using atomic layer deposition (ALD) process or the like. The silicon oxide layer 52 conformally covers the protrudent tip portion of the container 32, the exposed top surface of the silicon nitride layer 24, and the top surface of the implanted layer 26a within the stripe shaped regions 42.

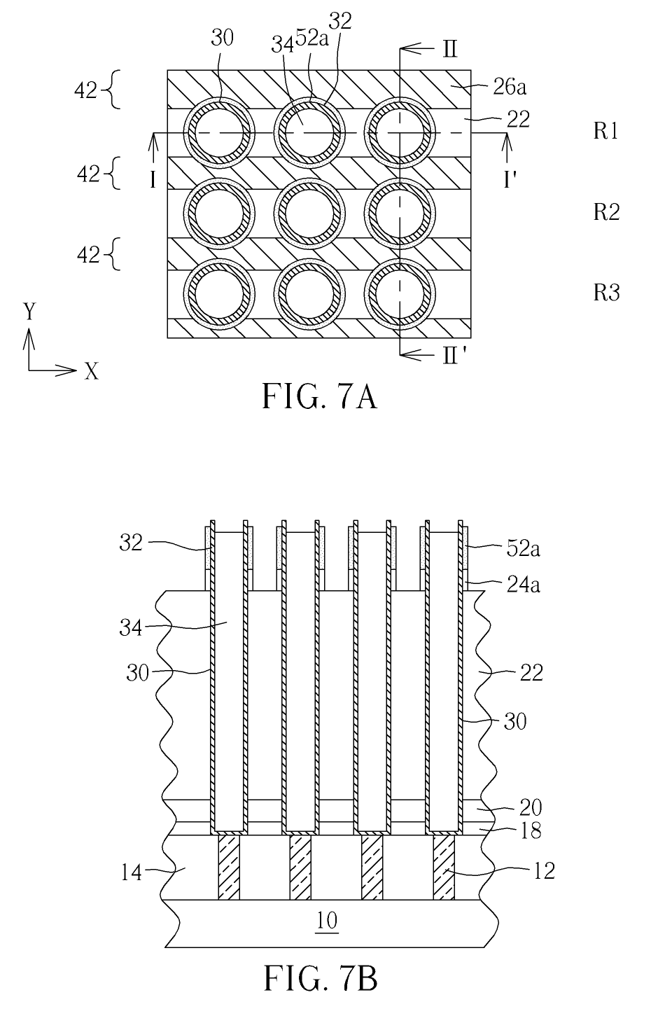

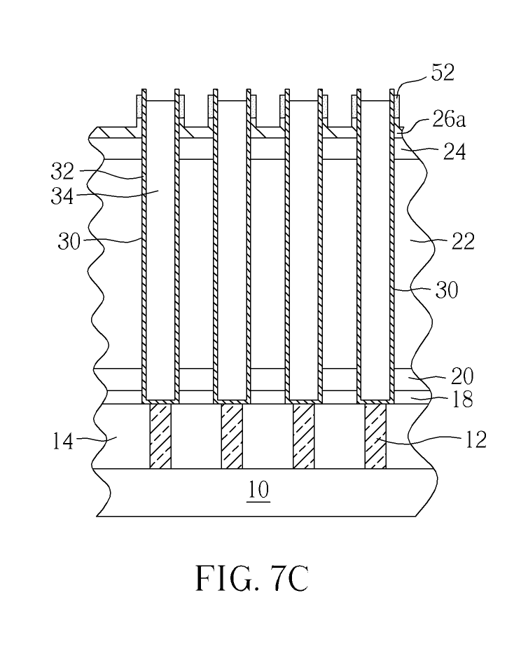

FIG. 7A is a plan view showing the containers after formation of an annular oxide spacer. FIG. 7B is a sectional view taken along line I-I′ of FIG. 7A, and FIG. 7C is a sectional view taken along line II-II′ of FIG. 7A. As shown in FIGS. 7A, 7B and 7C, an anisotropic dry etching process is carried out to etch the silicon oxide layer 52, thereby forming an annular oxide spacer 52a surrounding the protrudent tip portion of the container 32. Subsequently, the anisotropic dry etching process continues to etch the exposed silicon nitride layer 24 not covered by the implanted layer 26a to thereby form an annular nitride spacer 24a underneath the annular oxide spacer 52a. The annular nitride spacer 24a can be seen in FIG. 7B. A portion of the PSG layer 22 is revealed at this point.

As can be seen in FIG. 7C, the silicon nitride layer 24 within the stripe shaped regions 42 is masked by the implanted layer 26a. During the aforesaid anisotropic dry etching process, the implanted layer 26a acts as an etching hard mask that protect the silicon nitride layer 24 within the stripe shaped regions 42 from being etched. An upper portion of the implanted layer 26a may be consumed during the aforesaid anisotropic dry etching process. The annular nitride spacer 24a is structurally connected to the silicon nitride layer 24 within the stripe shaped regions 42.

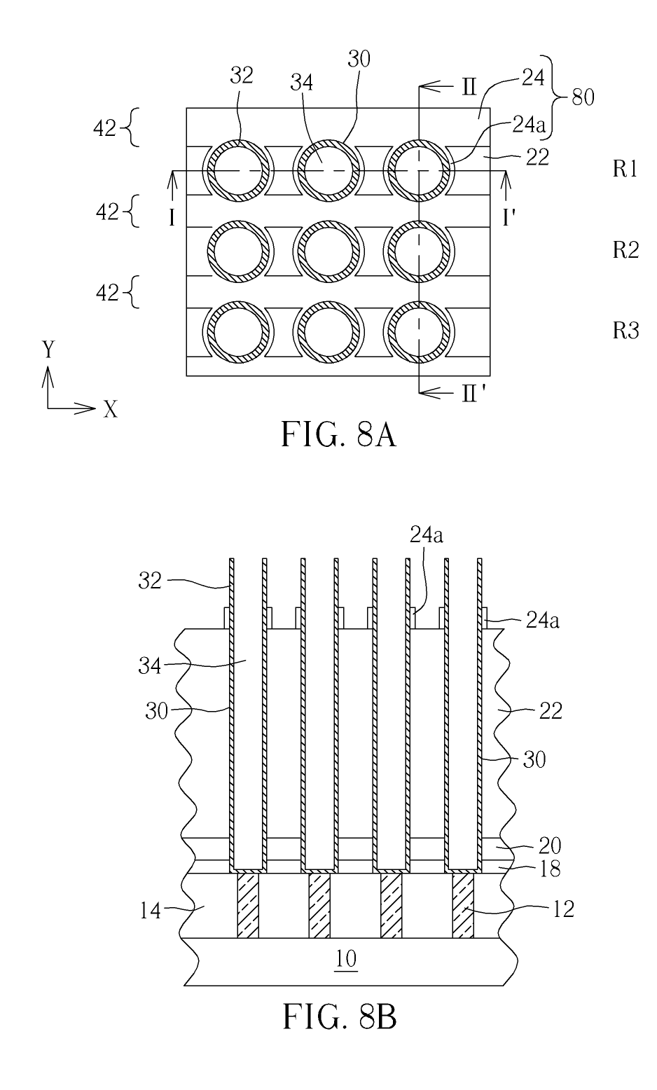

FIG. 8A is a plan view showing the containers after removal of the resist layer and the implanted layer. FIG. 8B is a sectional view taken along line I-I′ of FIG. 8A. As shown in FIGS. 8A and 8B, the resist layer 34 is completely removed from inside the container openings 30, thereby exposing the interior surface of the container 32. The resist layer 34 may be removed by using a conventional dry ash process. Subsequently, the annular oxide spacer 52a and the remaining implanted layer 26a are completely removed. The annular oxide spacer 52a and the remaining implanted layer 26a maybe removed by using a wet etching process with NH₄OH and dilute HF deglaze. The ammonium (NH₄OH) will selectively remove the remaining implanted layer 26a without attacking the metal, oxide and nitride.

As best seen in FIG. 8A, the annular nitride spacer 24a that clamps a neck portion of the container 32 is structurally connected to the silicon nitride layer 24 within the stripe shaped regions 42 to form a single-layer supporting structure 80. The annular nitride spacer 24a functions as a retaining ring that firmly holds the container 32, together with the silicon nitride layer 24 within the stripe shaped regions 42 extending along the reference x-axis. It is noteworthy that the annular nitride spacer 24a and the silicon nitride layer 24 within the stripe shaped regions 42 are situated in the same horizontal plane and are monolithic, i.e. formed from one single homogenous material layer, for example, in this embodiment, a single layer of silicon nitride. The annular nitride spacer 24a and the silicon nitride layer 24 within the stripe shaped regions 42 are both in direct contact with the neck portion of the container 32. It is noteworthy that the single-layer supporting structure 80 is not in contact with the uppermost tip portion of the container 32, but is only in contact with the neck portion of the container 32.

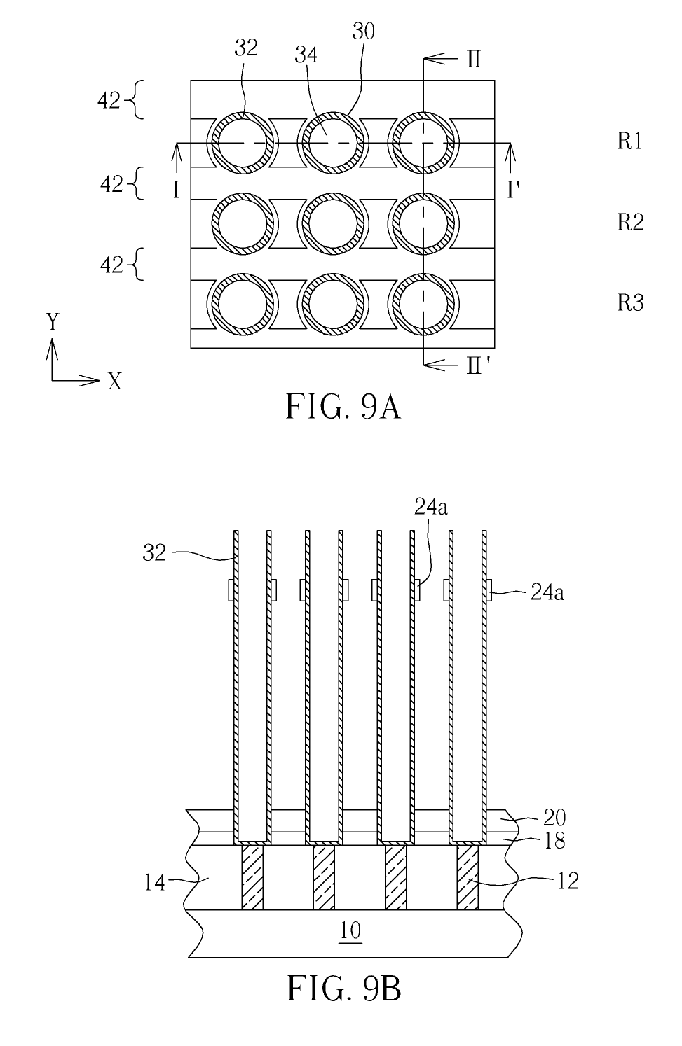

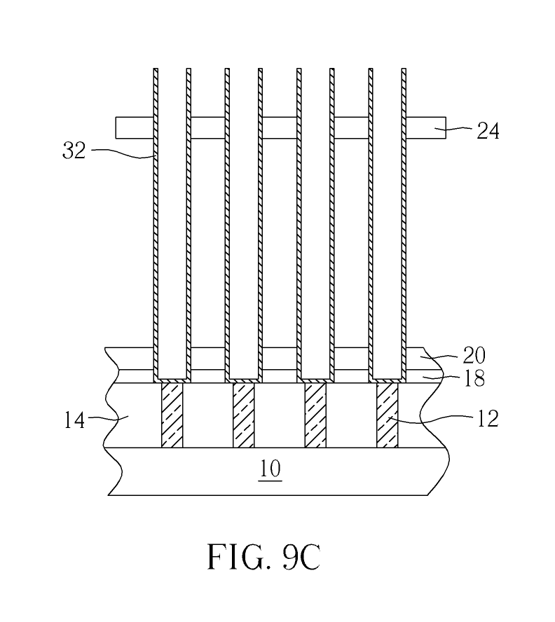

FIG. 9A is a plan view showing the containers after removal of the PSG layer. FIG. 9B is a sectional view taken along line I-I′ of FIG. 9A. FIG. 9C is a sectional view taken along line II-II′ of FIG. 9A. As shown in FIGS. 9A, 9B and 9C, an HF-based wet chemistry is used to completely remove the PSG layer 22, thereby exposing the outer sidewalls of the containers 32. It is to be understood that the thickness of the annular nitride spacer 24a may shrink due to the attack of diluted HF. It is possible that the annular nitride spacer 24a is completely consumed during the wet etching process, and in that case, each row of containers are only supported and clamped by the stripe shaped silicon nitride layer 24 within two adjacent regions 42.

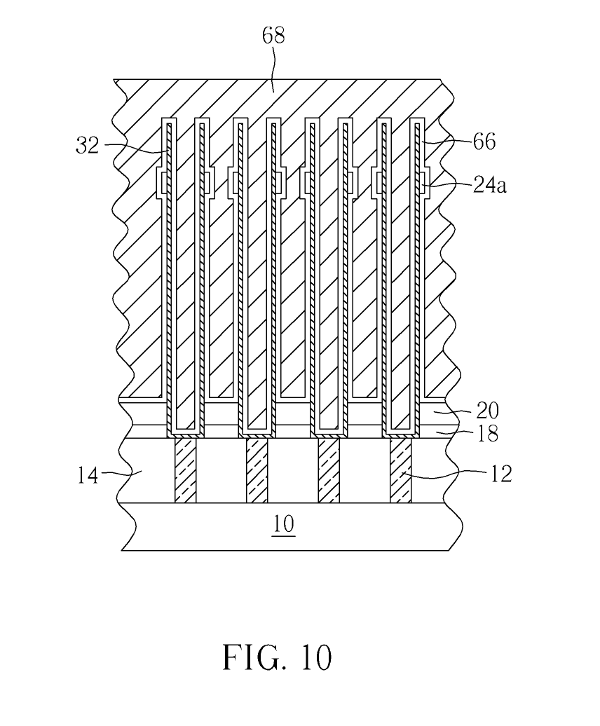

FIG. 10 is a sectional diagram showing a capacitor structure. As shown in FIG. 10, a chemical vapor deposition (CVD) process may be performed to deposit a conformal capacitor dielectric layer 66 on the outer sidewall and interior surface of the container 32. The capacitor dielectric layer 66 also conformally covers the annular nitride spacer 24a and the top surface of the USG layer 20. For example, the capacitor dielectric layer 66 may comprise ZrOx, but not limited thereto. A conductive layer 68 that acts as a top plate of the capacitor is then deposited on the capacitor dielectric layer 66. For example, the conductive layer 68 may comprise TiN, W, N⁺ doped poly, or combination thereof.

Those skilled in the art will readily observe that numerous modifications and alterations of the device and method may be made while retaining the teachings of the invention. Accordingly, the above disclosure should be construed as limited only by the metes and bounds of the appended claims.

1. A semiconductor structure, comprising:
a substrate having thereon at least one conductive region;
a plurality of cylinder-shaped container electrodes disposed on the substrate, wherein each of the cylinder-shaped container electrodes has a horizontal portion that is in direct contact with the at least one conductive region and a vertical sidewall portion connecting the horizontal portion; and
a supporting structure comprising a plurality of stripe shaped portions arranged in parallel to one another and a plurality rows of retaining rings alternately disposed between the plurality of stripe shaped portions, wherein each of the plurality of retaining rings retains each of the plurality of cylinder-shaped container electrodes, wherein the plurality of stripe shaped portions and the plurality of retaining rings are situated in the same horizontal plane.

2. The semiconductor structure according to claim 1 wherein the plurality of cylinder-shaped container electrodes are arranged in rows, and wherein each row of the cylinder-shaped container electrodes is clamped and sandwiched by two adjacent stripes of the plurality of stripe shaped portions.

3. The semiconductor structure according to claim 1 wherein the plurality of stripe shaped portions and the plurality of retaining rings are made from one single homogenous material layer.

4. The semiconductor structure according to claim 3 wherein the one single homogenous material layer is silicon nitride layer.

5. (canceled)

6. The semiconductor structure according to claim 1 wherein the plurality of stripe shaped portions and the plurality of retaining rings are both in direct contact with an upper portion of the vertical sidewall portion.

7. The semiconductor structure according to claim 6 wherein the supporting structure is not in contact with an uppermost tip portion of the vertical sidewall portion.

8. The semiconductor structure according to claim 1 wherein the at least one conductive region comprises a tungsten contact.

9. (canceled)
